(19) United States
(12) Patent Application Publication
(10) Pub. No.: US 2025/0294821 A1
(43) Pub. Date: Sep. 18, 2025

(54) SEMICONDUCTOR DEVICE AND MANUFACTURE METHOD OF THEREOF

(71) Applicant: HON HAI PRECISION INDUSTRY CO., LTD., New Taipei City (TW)

(72) Inventor: Min-Cheng CHEN, Hsinchu City (TW)

(21) Appl. No.: 18/621,148

(22) Filed: Mar. 29, 2024

(30) Foreign Application Priority Data
Mar. 13, 2024 (TW) 113109295

(51) Int. Cl. H01L 29/06; H01L 21/762; H01L 23/64; H01L 29/40; H01L 29/423; H01L 29/66

(52) U.S. Cl. CPC H10D 62/102; H01L 21/76224; H01L 23/647; H10D 30/023; H10D 64/01; H10D 64/513

(57) ABSTRACT

A semiconductor device is provided in some embodiments of the present disclosure, including: a substrate, a plurality of first conductive type doped regions, a plurality of second conductive type doped regions and a conductive contact. The plurality of first conductive type doped regions are disposed in the substrate. The plurality of second conductive type doped regions are disposed in the substrate. The conductive contact is disposed in the substrate, in which the first conductive type doped regions are between the conductive contact and the plurality of second conductive type doped regions. A method of manufacturing a semiconductor device is further provided in some embodiments of the present disclosure.

### CROSS-REFERENCE TO RELATED APPLICATION

This application claims priority to Taiwan Application Serial Number 113109295, filed Mar. 13, 2024, which is herein incorporated by reference.

### BACKGROUND

### Field of Invention

A semiconductor device and a manufacture method thereof are provided in some embodiments of the present disclosure.

### Description of Related Art

As the size of the semiconductor device gradually shrinks, the space between the internal elements also gradually shrinks. However, in the process of shrinking the space, external sources with different bias voltages (for example, one side is connected to a power cable and the other is grounded) may cause gate induced drain leakage (GIDL) due to band-to-band tunneling (BTBT). In order to prevent the accumulation of leakage current due to GIDL from causing an increase in basal voltage of elements, appropriate spaces need to be maintained between internal elements, but this setting will limit the process of shrinking the size of the semiconductor device.

Therefore, there is a need to provide a semiconductor device and a manufacture method thereof that can improve body effect caused by the rise in basal voltage and release more internal available spaces.

### SUMMARY

A semiconductor device is provided in some embodiments of the present disclosure, including: a substrate, a plurality of first conductive type doped regions, a plurality of second conductive type doped regions and a conductive contact. The plurality of first conductive type doped regions are disposed in the substrate. The plurality of second conductive type doped regions are disposed in the substrate. The conductive contact is disposed in the substrate, in which the plurality of first conductive type doped regions are disposed between the conductive contact and the plurality of second conductive type doped regions.

A method of manufacturing a semiconductor device is provided in some embodiments of the present disclosure, including: providing a substrate; forming a recess in the substrate; filling a contact material in the recess to form a conductive contact; doping a first conductive type dopant in the substrate to form a plurality of first conductive type doped regions; and doping a second conductive type dopant in the substrate to form a plurality of second conductive type doped regions, in which the plurality of first conductive type doped regions are disposed between the conductive contact and the plurality of second conductive type doped regions.

### BRIEF DESCRIPTION OF THE DRAWINGS

FIG. 1 to FIG. 3A and FIG. 4 to FIG. 6 exemplarily illustrate cross-sectional schematic diagrams of each intermediate stage in a method of manufacturing a semiconductor device according to some embodiments of the present disclosure.

FIG. 3B exemplarily illustrates a cross-sectional schematic diagram of one intermediate stage in a method of manufacturing a semiconductor device according to some other embodiments of the present disclosure.

### DETAILED DESCRIPTION

It is to be understood that different implementations or embodiments provided in the following may implement different features of the subject matter of the present disclosure. The embodiments of specific components and arrangements are used to simplify the disclosure and not to limit the disclosure.

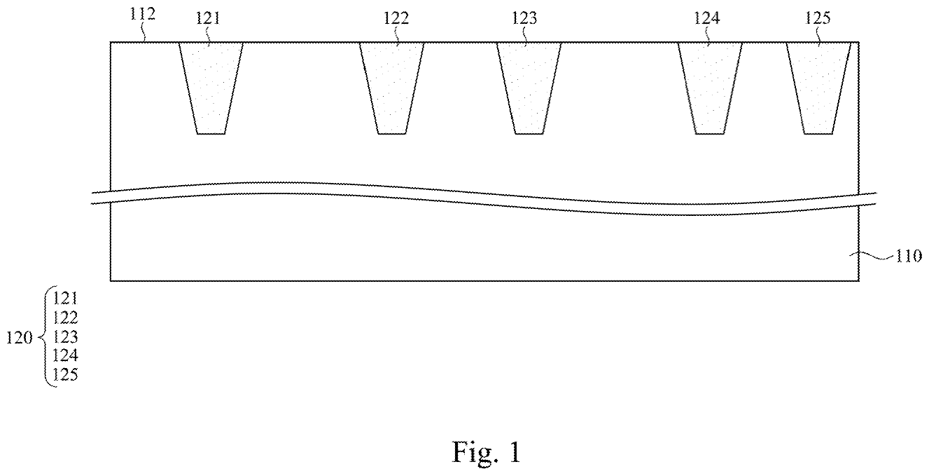

Refer to FIG. 1, a substrate 110 with an isolator 120 buried inside is provided.

In some embodiments, the step of providing the substrate 110 with the isolator 120 buried inside includes providing the substrate 110; forming a plurality of concave portions in the substrate 110; and depositing an insulation material in the concave portion to form a plurality of isolators 120 (a isolator 121, a isolator 122, a isolator 123, a isolator 124 and a isolator 125), so as to divide an upper surface 112 of the substrate 110 into a plurality of electrically isolated portions. In some embodiments, the isolator 120 can be formed by chemical vapor deposition (CVD), physical vapor deposition (PVD) or thermal oxidation.

In some embodiments, the materials of the substrate 110 include silicon, silicon germanium or a combination thereof. In some embodiments, a portion of region of the substrate 110 are doped with a specific semiconductor type dopant. For example, a portion of region is lightly doped with a first conductive type (such as N-type dopants, for example, phosphorus, arsenic, nitrogen, etc.) and another portion of the region is lightly doped with a second conductive type (such as P-type dopants, for example, boron, gallium, aluminum, etc.) to match the source and drain formed after subsequent doping treatment to assist the flow of electrons. In some embodiments, the insulation material used in the isolator 120 includes silicon oxide, silicon oxynitride, silicon hydroxide or a combination.

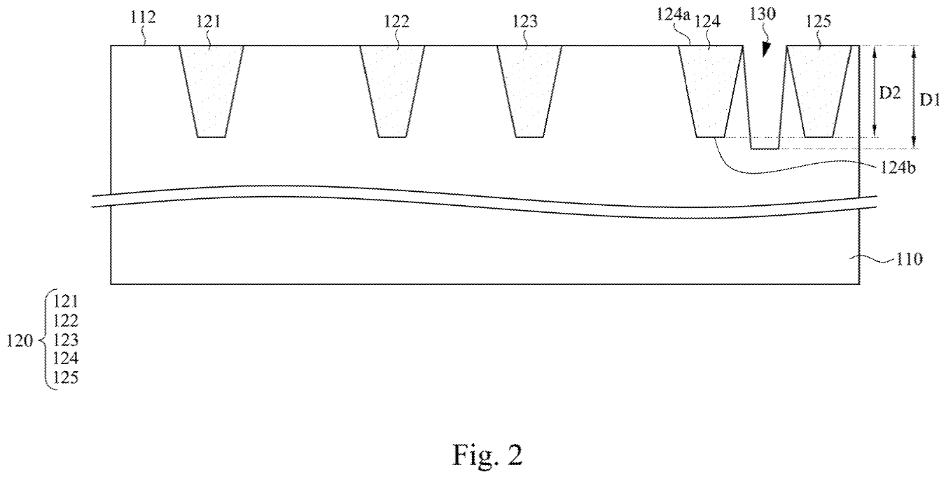

Refer to FIG. 2, a recess 130 is formed in the substrate 110.

In some embodiments, the step of forming the recess 130 in the substrate 110 includes: forming a mask on the substrate 110 and exposing a portion of the substrate 110 (not shown in figures); etching the exposed portion of the substrate 110, forming the recess 130; and removing the mask (such as, through chemical-mechanical polishing (CMP)) (not shown in figures).

In some embodiments, a recess 130 is adjacent to the isolator 124 and is disposed between the isolator 124 and the isolator 125 (adjacent to the isolator 124). In some embodiments, a depth D1 of the recess 130 is greater or equal to a depth D2 of the isolator 124 buried in the substrate 110 (that is, a distance that an upper surface 124a of the isolator 124 extends to a lower surface 124b, in which an upper surface 124a of the isolator 124 is substantially coplanar with an upper surface 112 of the substrate 110). In some other embodiments, the depth D1 of recess 130 is less than (not including “equal to”) the depth D2 of the isolator 124 buried in the substrate 110. By controlling the depth D1 of the recess 130, the depth of the subsequent formed conductive contact can be controlled.

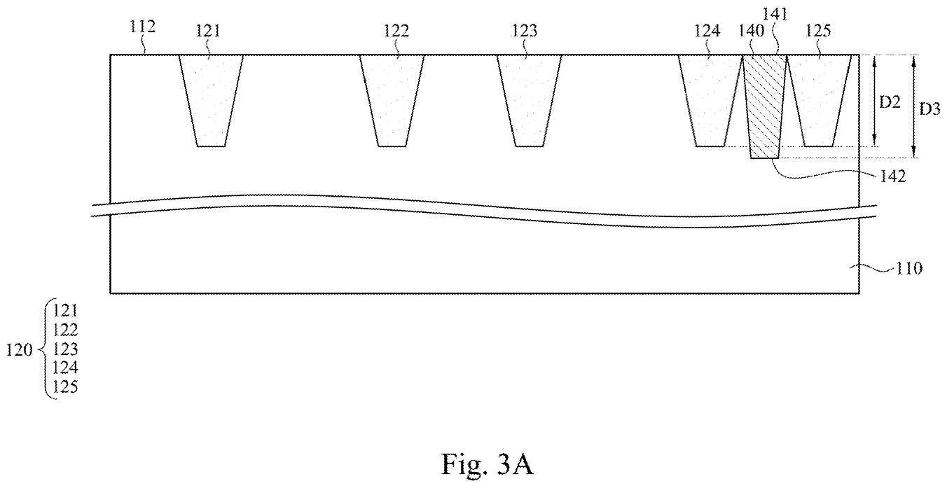

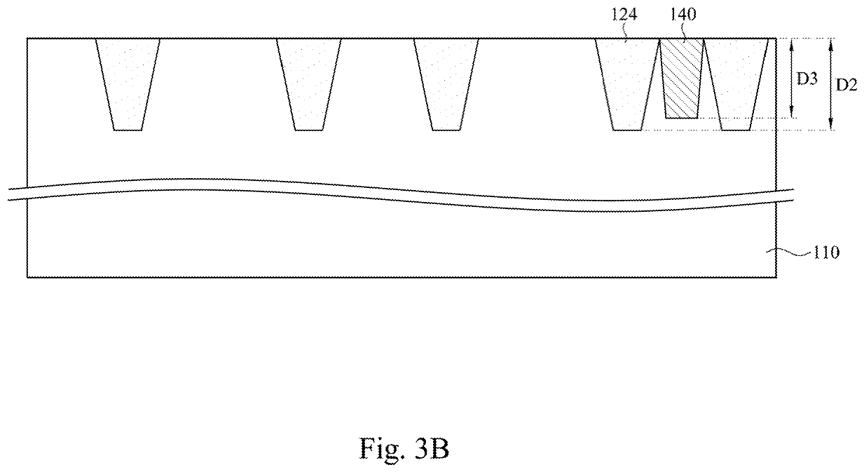

Refer to FIG. 2 and FIG. 3A, a contact material in the recess 130 is filled to form a conductive contact 140.

In some embodiments, a contact material includes a conductive material (such as metal), the parasitic substrate resistance of substrate 110 can be reduced, and through the subsequent connection to the ground terminal, the latch-up phenomenon can be reduced, in which the latch-up phenomenon is caused by the rise of the substrate voltage driving the low-impedance conduction path between subsequent adjacent doped regions of different conductive types. In some embodiments, a contact material further includes silicon, silicon germanium or a combination thereof. By matching the conductive material, the heat resistance of the conductive contact 140 can be further improved and the integration with the substrate 110 can be improved.

In some embodiments, the conductive contact 140 can be formed by the deposition process. In some embodiments, the contact material fills up the recess 130, therefore, a depth D3 of the conductive contact 140 (extending inwardly from the upper surface 141 to the lower surface 142, where the upper surface 141 is approximately coplanar with the upper surface 112 of the substrate 110) is the same as the depth D1 of the recess 130. In some embodiments, the depth D3 of the conductive contact 140 is greater than the depth D2 of the isolator 124 buried in the substrate 110. Generally speaking, the larger the depth D3, the conductive contact 140 can have a better effect of reducing the leakage current. However, if the depth D3 is too deep (such as, twice of the depth of the first conductive type doped regions 150, 151, 152, 153 or the second conductive type doped regions 160, 161, 162, 163), the volume occupied by the conductive contact 140 will be too large, which will overly compress the installation space of other elements. In some other embodiments, please refer to FIG. 3B, the depth D3 of the conductive contact 140 is less than (not including “equal to”) the depth D2 of the isolator 124 buried in the substrate 110.

In some embodiments, after the step of filling the contact material in the recess 130, the method includes forming a dummy grate structure (not shown in figures) on the substrate 110. Through the setting of the dummy grate structure, the dopant can be blocked in the subsequent doping process and the region to be doped in the substrate 110 can be exposed, thereby locating the doping position of the subsequent dopant.

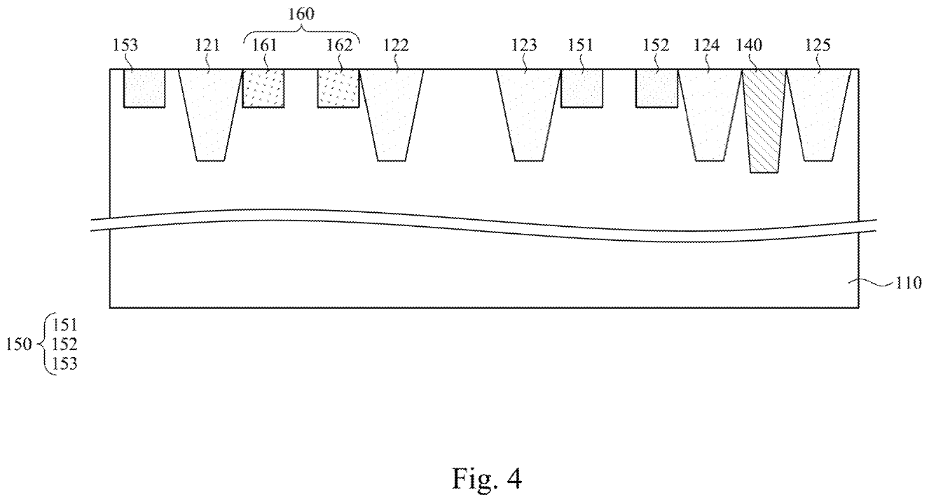

Refer to FIG. 4, the first conductive type dopant is doped in the substrate 110 to form a plurality of first conductive type doped regions 150 (the first conductive type doped region 151, the first conductive type doped region 152 and the first conductive type doped region 153); and the second conductive type dopant is doped in the substrate 110 to form a plurality of second conductive type doped regions 160 (the second conductive type doped region 161 and the second conductive type doped region 162).

In some embodiments, the first conductive type doped region 151 and the first conductive type doped region 152 are deposed between the conductive contact 140 and the second conductive type doped region 160. That is, the conductive contact 140 is disposed at a side of the first conductive type doped region 152 which is away from the second conductive type doped region 160. In some embodiments, the conductive contact 140 is between the isolator 124 and the isolator 125, the conductive contact 140 is electrically isolated from other conductive type doped regions (such as the first conductive type doped region 152) through the isolator 124 and the isolator 125, and the isolator 124 and the isolator 125 can avoid the diffuse of the conductive material of the conductive contact 140, thereby preventing mutual interference of electrons between the conductive contact 140 and the first conductive type doped region 152.

In some embodiments, the first conductive type dopant and the second conductive type dopant are respectively N-type dopants (such as phosphorus, arsenic, nitrogen, etc.) and P-type dopants (such as boron, gallium, aluminum, etc.), or the first conductive type dopant and the second conductive type dopant are respectively P-type dopants and N-type dopants. Generally, people with common knowledgeable can select appropriate dopants according to the requirements to match the subsequent applied voltage.

In some embodiments, the step of doping the first conductive type dopant in the substrate 110 includes forming the first conductive type doped region 151 and the first conductive type doped region 152 adjacent to the isolator 124, allowing the isolator 124 to be deposited between the first conductive type doped regions (151, 152) and the conductive contact 140, and there is no isolator between the first conductive type doped region 151 and the first conductive type doped region 152. In some embodiments, the first conductive type doped region 151 and the first conductive type doped region 152 are deposited between the isolator 124 and the isolator 123 and electrically isolated from other doped regions via the isolators 123, 124.

In some embodiments, the step of doping the second conductive type dopant in the substrate 110 includes forming a second conductive type doped region 161 and a second conductive type doped region 162 adjacent to the isolator 124 to allow the isolator 122 to be deposited between the first conductive type doped region 151 and the second conductive type doped region 162. In some embodiments, the second conductive type doped region 161 and the second conductive type doped region 162 are deposited between the isolator 121 and the isolator 122. Through electrical isolation from other doped regions by the isolators 121,122, and no isolator disposed between the second conductive type doped region 161 and the second conductive type doped region 162, the channel region after subsequent external bias voltage is remained. For example, the second conductive type doped region 161 and the first conductive type doped region 153 (located at a side of the second conductive type doped region 161 away from the first conductive type doped regions 151 and 152) are electrically isolated via the isolator 121, and the second conductive type doped region 162 and the first conductive type doped region 151 are electrically isolated via the spacer 122.

In some embodiments, before performing the doping process, the region to be doped is positioned by disposing the dummy grate structure, and after the step of doping the first conductive type dopant in the substrate 110 and doping the second conductive type dopant in the substrate 110, the dummy grate structure is removed.

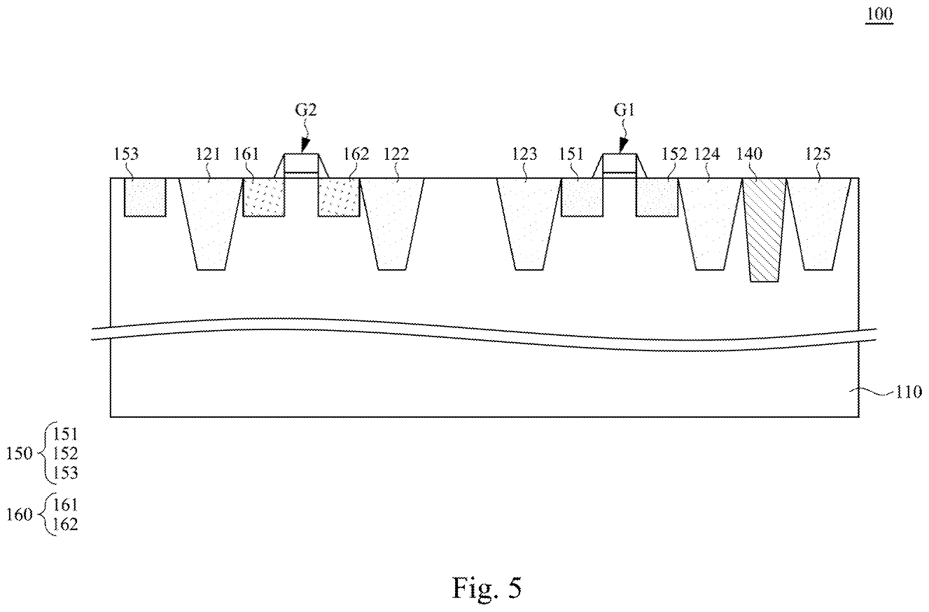

Refer to FIG. 5, a first gate G1 is formed on the substrate 110 and contacts the first conductive type doped region 151 and the first conductive type doped region 152, and a second gate G2 is formed on the substrate 110 and contacts the second conductive type doped region 161 and the second conductive type doped region 162, thereby obtaining a semiconductor device 100.

In some embodiments, the first gate G1 includes a first gate dielectric layer on the substrate 110, and the first gate layer on the first gate dielectric layer (not shown in figures). In some embodiments, a second gate G2 includes a second gate dielectric layer on the substrate 110, and a second gate layer on the second gate dielectric layer (not shown in figures). Subsequently, by applying a specific bias voltage to the first gate G1 and the second gate G2, a first channel region and a second channel region can be formed below the first gate G1 and the second gate G2, respectively.

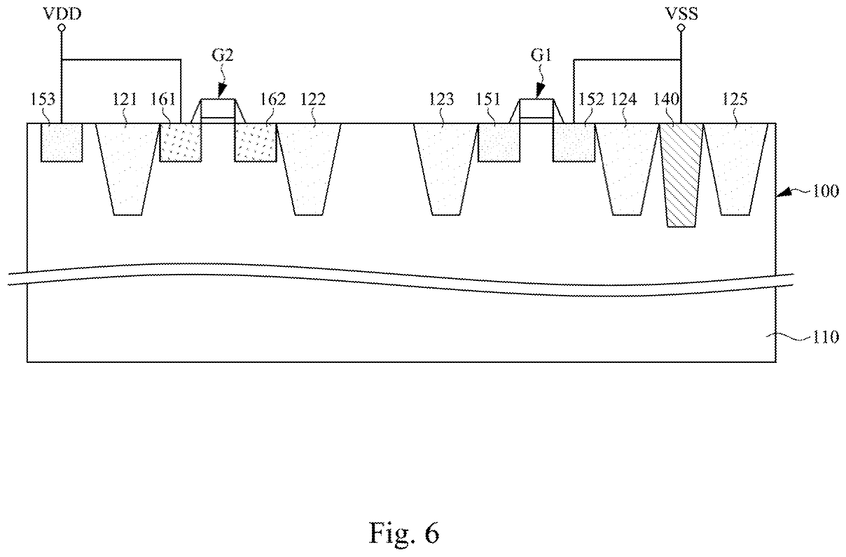

Refer to FIG. 6, a ground terminal VSS is electrically connected to the first conductive type doped region 152 and the conductive contact 140, and a power cable VDD is electrically connected to the first conductive type doped region 153 and the second conductive type doped region 161.

In some embodiments, a power cable VDD provides a first bias voltage to the second conductive type doped region 161 to allow the second conductive type doped region 161 to be served as a source and the second conductive type doped region 162 to be served as a drain. Meanwhile, a second gate G2 also receives a second bias voltage. Through the applied voltage difference, electrons flow between the second conductive type doping region 161 and the second conductive type doping region 162, and a channel region is formed in the substrate 110 adjacent to the second gate G2.

In some embodiments, a circuit structure disposed in the substrate 110 electrically connects to the second conductive type doped region 161 and the first conductive type doped region 152 to allow the current to flow between a power cable VDD and a ground terminal VSS.

It should be noted that since there is a bias voltage difference between the second conductive type doped region 161 connected to a power cable VDD and the first conductive type doped region 152 connected to the ground terminal VSS, band-to-band tunneling (BTBT) can easily occur and cause GIDL if the distance between the two regions is insufficient (for example, the element density is too high or the substrate is too small). At this time, electrons will tunnel directly from the region of the second conductive type doped region 161 (connected to a power cable VDD) to the first conductive type doped region 152 (connected to the ground terminal VSS), without going through the circuit structure that is electrically connected between the two regions, and low-impedance conduction path generated at the bottom of the substrate causes a latch-up effect, which will cause current loss and reduce current conduction efficiency.

In order to avoid the aforementioned latch-up effect, the following methods may be tried to improve the latch-up effect in the conventional manufacture process of a semiconductor device. For example, an appropriate space is maintained between adjacent doped regions, or it is possible to further form the silicon germanium epitaxial region in the region adjacent to the doped region when forming the doped region, and the doped region and the silicon germanium epitaxial region are jointly connected to the ground terminal VSS to assist the flow of current through the silicon germanium epitaxial region.

However, the method of maintaining the space will cause the element size and density to be limited to a specific value, and the elements cannot continue to shrink. Since it has high requirements on the lattice structure (lattice defects will cause the risk of leakage) for preparing the silicon germanium epitaxial region, the requirements for process technology are high. In addition, the silicon germanium epitaxial region is limited by the depth limit of the epitaxial process (usually the depth can only be approximately equal to the doping region), and the depth of the silicon germanium epitaxial region that can be extended in the substrate is limited, which also limits the effect of reduction of leakage current.

Relatively, the present disclosure can reduce the parasitic substrate resistance by arranging the conductive contact 140 on a side of the first conductive type doped region 152 that is externally grounded to the ground terminal VSS and by allowing the conductive contact 140 and the first conductive type doped region 152 to be grounded together. By utilizing the low resistance of the conductive material, the parasitic substrate resistance can be reduced to improve the body effect caused by leakage current due to GIDL, and current conduction efficiency can be improved. In addition, since the conductive contact 140 is obtained by filling the recess with the conductive material (for example, please refer to the recess 130 in FIG. 2), the conductive contact 140 of appropriate depth can be prepared according to the design requirements, and the flexibility for manufacturing the deep area is improved. Furthermore, compared with the setting of the silicon-germanium epitaxial region, the conductive contact 140 is not limited to the upper limit of the depth of the epitaxial method, the buried depth can be further increased and the body effect can be further improved.

It is also worth mentioning that due to the arrangement of the conductive contact 140, the latch-up effect can be improved. There is no need to deliberately reserve a specific space between the sources of the semiconductor device 100 in the present disclosure to avoid the latch-up effect. Therefore, the internal space of the semiconductor device 100 can be released and the utilization rate of the internal space can be improved.

Although this disclosure has been described in detail with respect to certain embodiments, other embodiments are possible. Accordingly, the spirit and scope of the appended claims should not be limited to the embodiments described herein.

What is claimed is:

1. A semiconductor device, comprising:
a substrate;
a plurality of first conductive type doped regions, disposed in the substrate;
a plurality of second conductive type doped regions, disposed in the substrate; and
a conductive contact, disposed in the substrate, wherein the plurality of first conductive type doped regions are disposed between the conductive contact and the plurality of second conductive type doped regions.

2. The semiconductor device of claim 1, wherein the conductive contact comprises a conductive material.

3. The semiconductor device of claim 2, wherein the conductive contact further comprising silicon, silicon germanium or a combination thereof.

4. The semiconductor device of claim 1, further comprising a first isolator, disposed in the substrate and between the plurality of first conductive type doped regions and the conductive contact.

5. The semiconductor device of claim 4, wherein a depth of the conductive contact buried in the substrate is greater than a depth of a first isolator buried in the substrate.

6. The semiconductor device of claim 1, further comprising a second isolator, disposed between the plurality of first conductive type doped regions and the plurality of second conductive type doped regions.

7. The semiconductor device of claim 1, further comprising:
a first gate, disposed on the substrate and contacting the plurality of first conductive type doped regions; and
a second gate, disposed on the substrate and contacting the plurality of second conductive type doped regions.

8. The semiconductor device of claim 1, wherein one of the plurality of first conductive type doped regions is electrically connected to a ground terminal, and one of the plurality of second conductive type doped regions is electrically connected to a power cable.

9. A method of manufacturing a semiconductor device, comprising:
providing a substrate;
forming a recess in the substrate;
filling a contact material in the recess to form a conductive contact;
doping a first conductive type dopant in the substrate to form a plurality of first conductive type doped regions; and
doping a second conductive type dopant in the substrate to form a plurality of second conductive type doped regions, wherein the plurality of first conductive type doped regions are disposed between the conductive contact and the plurality of second conductive type doped regions.

10. The method of claim 9, wherein
before the step of forming the recess in the substrate, the method comprises forming a first isolator in the substrate;
the step of forming the recess in the substrate comprises forming the recess adjacent to the first isolator; and
the step of doping the first conductive type dopant in the substrate comprises forming the plurality of first conductive type doped regions adjacent to the first isolator to allow the first isolator to be disposed between the plurality of first conductive type doped regions and the conductive contact.

11. The method of claim 10, wherein a depth of the recess is greater than a depth of the first isolator buried in the substrate.

12. The method of claim 9, wherein before forming the recess in the substrate, the method comprises forming a second isolator in the substrate and disposed between the plurality of first conductive type doped regions and the plurality of second conductive type doped regions.

13. The method of claim 9, wherein,
after the step of filling the contact material in the recess, the method comprises forming a dummy grate structure on the substrate; and
after the steps of doping the first conductive type dopant in the substrate and doping the second conductive type dopant in the substrate, the method comprises removing the dummy grate structure.

14. The method of claim 9, wherein
after the steps of doping the first conductive type dopant in the substrate and doping the second conductive type dopant in the substrate, the method comprises:
forming a first gate on the substrate and contacting the plurality of first conductive type doped regions; and
forming a second gate on the substrate and contacting the plurality of second conductive type doped regions.

15. A semiconductor device, comprising:
a substrate;
a plurality of first conductive type doped regions, disposed in the substrate;
a first isolator, disposed in the substrate, adjacent to the plurality of first conductive type doped regions; and
a conductive contact, disposed in the substrate, wherein the first isolator is disposed between the plurality of first conductive type doped regions and the conductive contact.

16. The semiconductor device of claim 15, wherein a depth of the conductive contact buried in the substrate is greater than a depth of the first isolator buried in the substrate.

17. The semiconductor device of claim 15, further comprising:
a first gate, disposed on the substrate and contacting the plurality of first conductive type doped regions.

18. The semiconductor device of claim 15, further comprising a plurality of second conductive type doped regions, disposed in the substrate, wherein the plurality of first conductive type doped regions are disposed between the plurality of second conductive type doped regions and the conductive contact.

19. The semiconductor device of claim 18, further comprising a second isolator, disposed between the plurality of first conductive type doped regions and the plurality of second conductive type doped regions.

20. The semiconductor device of claim 18, further comprising:
a second gate, disposed on the substrate and contacting the plurality of second conductive type doped regions.
